(19) United States
(12) Patent Application Publication
(10) Pub. No.: US 2025/0359019 A1
(43) Pub. Date: Nov. 20, 2025

(54) SEMICONDUCTOR MEMORY DEVICE

(71) Applicant: Samsung Electronics Co., Ltd., Suwon-si, (KR)

(72) Inventors: Teawon KIM, Suwon-si (KR); Jihyun KHO, Suwon-si (KR); Yurim KIM, Suwon-si (KR); Seunghee LEE, Suwon-si (KR); Yong-Suk TAK, Suwon-si (KR)

(21) Appl. No.: 18/945,708

(22) Filed: Nov. 13, 2024

(30) Foreign Application Priority Data
May 17, 2024 (KR) 10-2024-0064570

(51) Int. Cl. H10B 12/00

(52) U.S. Cl. CPC H10B 12/315; H10B 12/05

(57) ABSTRACT

A semiconductor memory device, comprising: a bit line on substrate, wherein the bit line extends in a first direction that is parallel with an upper surface of the substrate; a channel structure on the bit line, wherein the channel structure extends in a second direction that is parallel with the upper surface of the substrate, and wherein the channel structure includes a vertical part extending in a third direction that is perpendicular to the upper surface of the substrate; a word line on the channel structure; a pad contact layer on the vertical part of the channel structure; a landing pad on the pad contact layer; and a capacitor structure electrically connected to the landing pad, wherein the pad contact layer includes a bottom part on a lower surface of the landing pad.

### CROSS-REFERENCE TO RELATED APPLICATIONS

This application claims priority to Korean Patent Application No. 10-2024-0064570, filed in the Korean Intellectual Property Office on May 17, 2024, the entire contents of which are hereby incorporated by reference.

### BACKGROUND OF THE INVENTION

### Field of the Invention

The present disclosure relates to semiconductor devices. More particularly, the present disclosure relates to semiconductor memory devices.

### Description of Related Art

A semiconductor device may be an important component used to control or amplify an electrical signal in an electronic device, and various types of semiconductor devices are manufactured. For example, a semiconductor memory device may be mainly used to store and retrieve data, while a non-memory semiconductor device may be used to control or amplify an electrical signal. The semiconductor device may play an important role in various fields including computers, communication equipment, consumer electronics, etc.

With the development of industry, the performance and function requirements of the electronic devices are also increasing. Accordingly, high-performance characteristics of the semiconductor devices may be needed, and the degree of integration of the semiconductor devices is increasing to meet these needs. Accordingly, a transistor with a vertical channel has been proposed to improve the degree of integration of semiconductor device.

### SUMMARY OF THE INVENTION

The present disclosure may provide semiconductor memory devices with improved electrical characteristics and reliability.

According to some embodiments of the present disclosure, by placing the pad contact layer between the channel structure and the landing pad, the contact resistance between the pad contact layer and the channel structure and between the pad contact layer and the landing pad can be reduced. Accordingly, electrical characteristics and reliability of the semiconductor memory device can be improved.

According to some embodiments of the present disclosure, a semiconductor memory device, comprising: a substrate; a bit line on the substrate, wherein the bit line extends in a first direction that is parallel with an upper surface of the substrate; a channel structure on the bit line, wherein the channel structure extends in a second direction that is parallel with the upper surface of the substrate and perpendicular to the first direction, and wherein the channel structure includes a vertical part extending in a third direction that is perpendicular to the upper surface of the substrate; a word line on the channel structure; a pad contact layer on the vertical part of the channel structure; a landing pad on the pad contact layer; and a capacitor structure electrically connected to the landing pad, wherein the pad contact layer includes a bottom part on a lower surface of the landing pad.

According to some embodiments of the present disclosure, a semiconductor memory device, comprising: a substrate; a bit line on the substrate, wherein the bit line extends in a first direction that is parallel with an upper surface of the substrate; a channel structure on the bit line, wherein the channel structure extends in a second direction that is parallel with the upper surface of the substrate and perpendicular to the first direction, wherein the channel structure includes a first vertical part extending in a third direction that is perpendicular to the upper surface of the substrate, and wherein the channel structure further includes a second vertical part that is spaced apart from the first vertical part in the first direction; a first word line on a side surface of the first vertical part and extending in the second direction; a second word line on a side surface of the second vertical part and extending in the second direction; a gate separation structure between the first word line and the second word line in the first direction; an interlayer insulating film on the gate separation structure; a contact trench in the interlayer insulating film, wherein the contact trench overlaps a portion of the channel structure and a portion of the gate separation structure in the third direction; a pad contact layer in the contact trench, wherein the pad contact layer is in contact with the channel structure; a landing pad on the pad contact layer; and a capacitor structure electrically connected to the landing pad.

According to some embodiments of the present disclosure, a semiconductor memory device, comprising: a substrate; a bit line on the substrate, wherein the bit line extends in a first direction that is parallel with an upper surface of the substrate; a channel structure on the bit line, wherein the channel structure extends in a second direction that is parallel with the upper surface of the substrate and perpendicular to the first direction, and wherein the channel structure includes a first vertical part extending in a third direction that is perpendicular to the upper surface of the substrate, and wherein the channel structure further includes a second vertical part that is spaced apart from the first vertical part in the first direction; a first word line on a side surface of the first vertical part and extending in the second direction; a second word line on a side surface of the second vertical part and extending in the second direction; a gate separation structure between the first word line and the second word line in the first direction; a pad contact layer on an upper surface of the first vertical part; a landing pad on the pad contact layer; and a capacitor structure electrically connected to the landing pad, wherein the pad contact layer is between the landing pad and the first vertical part and between the landing pad and the gate separation structure, wherein the landing pad includes a first element at a first concentration, wherein the pad contact layer includes the first element at a second concentration, and wherein the second concentration is greater than the first concentration.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view provided to explain a semiconductor memory device according to some embodiments of the present disclosure;

FIG. 2 is a cross-sectional view taken along line A-A′ of FIG. 1;

FIG. 3 is an enlarged view provided to explain a region Q1 of FIG. 2;

FIG. 4 is a diagram schematically illustrating the concentrations of a first element and a second element along LINE1 of FIG. 3;

FIG. 5 is a cross-sectional view taken along line B-B′ of FIG. 1;

FIG. 6 is a cross-sectional view taken along line C-C′ of FIG. 1;

FIG. 7 is a cross-sectional view taken along line D-D′ of FIG. 1;

FIG. 8 is a diagram provided to explain a semiconductor memory device according to some embodiments of the present disclosure;

FIG. 9 is a diagram provided to explain a semiconductor memory device according to some embodiments of the present disclosure;

FIG. 10 is a diagram provided to explain a semiconductor memory device according to some embodiments of the present disclosure;

FIG. 11 is a diagram provided to explain a semiconductor memory device according to some embodiments of the present disclosure;

FIG. 12 is a diagram provided to explain a semiconductor memory device according to some embodiments of the present disclosure;

FIGS. 13 to 19 are diagrams showing intermediate stages, provided to explain a method for manufacturing a semiconductor memory device according to some embodiments of the present disclosure;

FIGS. 20 and 21 are diagrams showing intermediate stages, provided to explain a method for manufacturing a semiconductor memory device according to some embodiments of the present disclosure.

FIGS. 22 and 23 are diagrams showing intermediate stages, provided to explain a method for manufacturing a semiconductor memory device according to some embodiments of the present disclosure.

### DETAILED DESCRIPTION

In the present disclosure, spatially relative terms, such as “beneath,” “below,” “lower,” “under,” “above,” “upper,” and the like, may be used herein for ease of explanation to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

Hereinafter, a semiconductor memory device and a method for manufacturing the same according to some embodiments of the present disclosure will be described in detail with reference to drawings.

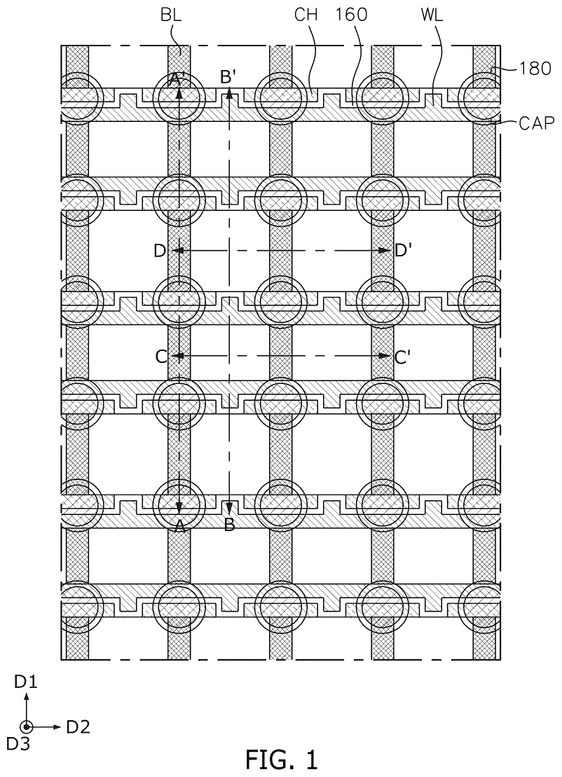

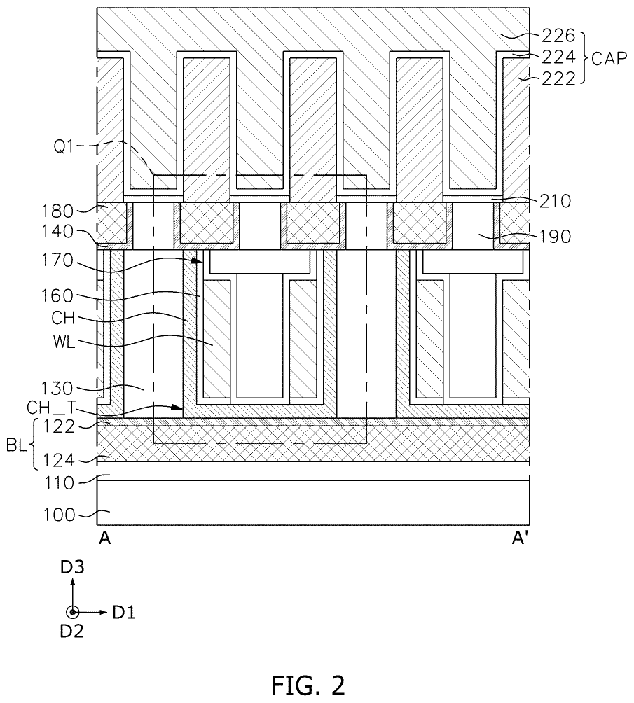

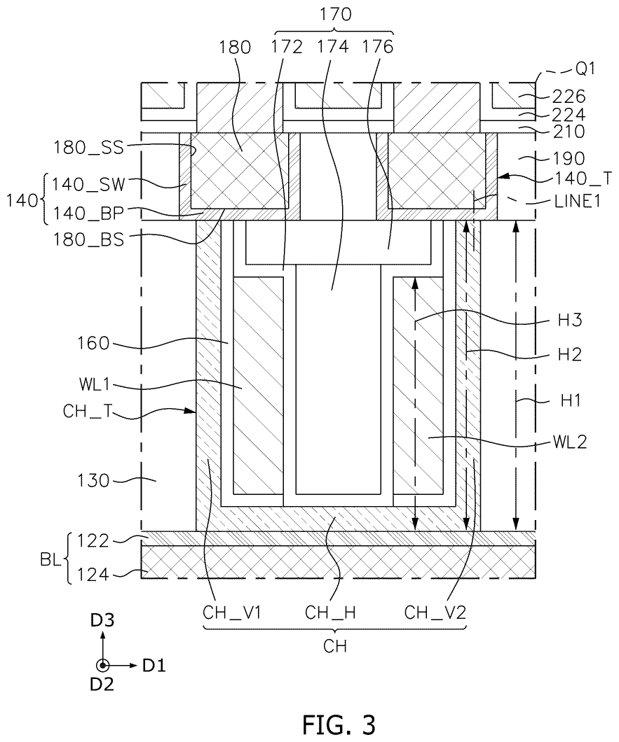

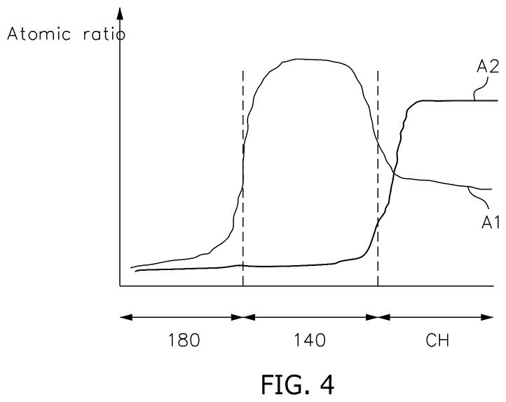

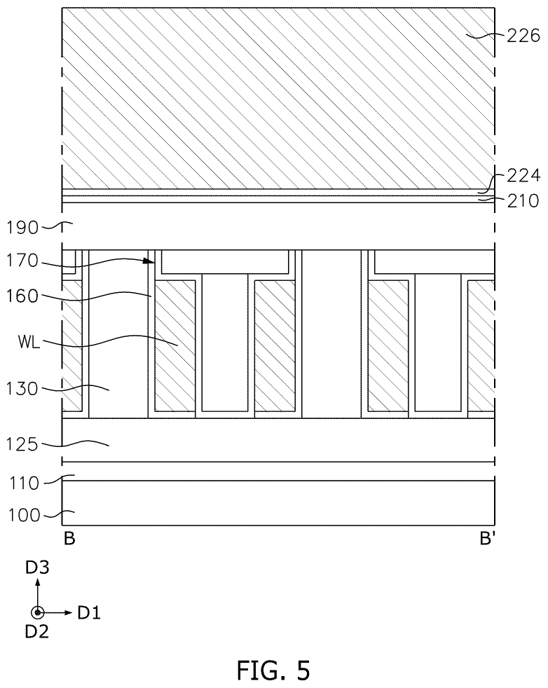

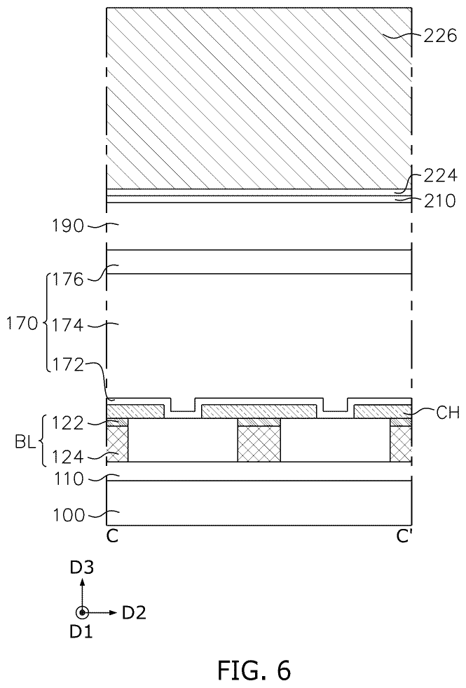

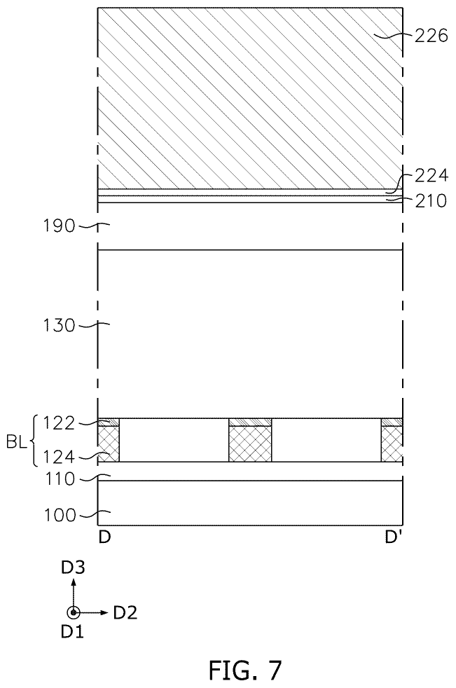

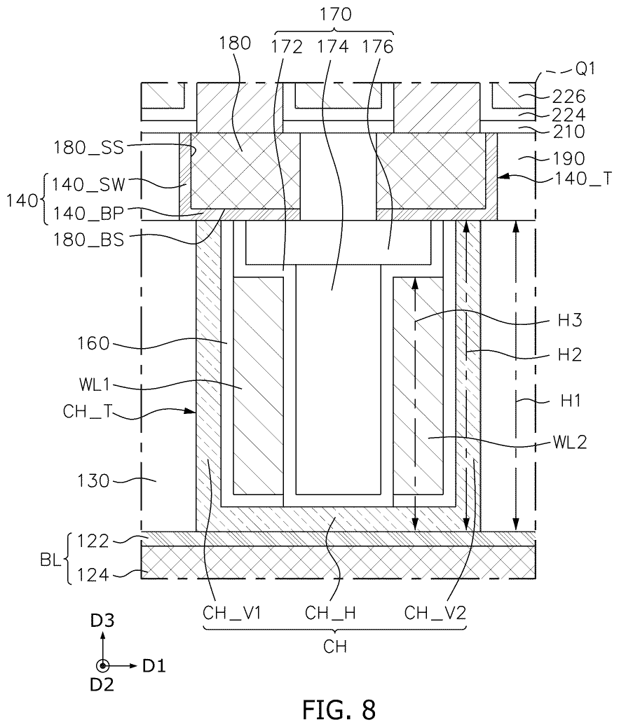

FIG. 1 is a plan view provided to explain a semiconductor memory device according to some embodiments of the present disclosure. FIG. 2 is a cross-sectional view taken along line A-A′ of FIG. 1. FIG. 3 is an enlarged view provided to explain a region Q1 of FIG. 2. FIG. 4 is a diagram schematically illustrating the concentrations of a first element and a second element along LINE1 of FIG. 3. FIG. 5 is a cross-sectional view taken along line B-B′ of FIG. 1. FIG. 6 is a cross-sectional view taken along line C-C′ of FIG. 1. FIG. 7 is a cross-sectional view taken along line D-D′ of FIG. 1. FIG. 8 is a diagram provided to explain a semiconductor memory device according to some embodiments of the present disclosure. For reference, a dielectric film 224 and an upper electrode 226 of a capacitor structure CAP are omitted and not illustrated in FIG. 1.

The semiconductor memory device according to some embodiments of the present disclosure may include memory cells including a vertical channel transistor (VCT). The vertical channel transistor may refer to a transistor with its channel length extending in a direction (e.g., a third direction D3) perpendicular to an upper surface of the semiconductor substrate.

Referring to FIGS. 1 to 8, the semiconductor memory device according to some embodiments may include a substrate 100, a wiring insulating film 110, a bit line BL, a channel structure CH, a word line WL, a bit line insulating film 125, a mold pattern 130, a pad contact layer 140, a gate insulating film 160, a gate separation structure 170, a landing pad 180, an interlayer insulating film 190, and a capacitor structure CAP.

The substrate 100 may be a semiconductor substrate. For example, the substrate 100 may include silicon (Si), silicon germanium (SiGe), indium antimonide (InSb), lead telluride (PbTe), indium arsenide (InAs), indium phosphide (InP), gallium arsenide (GaAs), gallium antimonide (GaSb), etc. However, aspects are not limited to the above.

In some embodiments, a plurality of transistors (electrically) connected to the bit line BL may be disposed in the substrate 100. For example, a sensing transistor, a transmission transistor, a driving transistor, etc. may be disposed in the substrate 100. The type of the transistors may vary depending on the layout design of the semiconductor memory device. A region in the substrate 100 where the plurality of transistors are disposed may be referred to as a peripheral circuit area.

The wiring insulating film 110 may be disposed on the substrate 100. In some embodiments, a wiring structure may be disposed in the wiring insulating film 110. The wiring structure may (electrically) connect the substrate 100 and the bit line BL. For example, the plurality of transistors disposed in the substrate 100 may be (electrically) connected to the bit line BL through the wiring structure.

The bit line BL may be disposed on the wiring insulating film 110. The bit line BL may extend in the first direction D1 on the wiring insulating film 110. Adjacent bit lines BL of a plurality of bit lines BL may be disposed to be spaced apart from each other in a second direction D2. The second direction D2 may be a direction that intersects (that is perpendicular to) the first direction D1. In some embodiments, the first direction D1 and the second direction D2 may be parallel with an upper surface of the substrate 100. In some embodiments, an upper surface of the bit line BL and an upper surface of the bit line insulating film 125 may be disposed on the same plane each other. For example, the upper surface of the bit line BL and the upper surface of the bit line insulating film 125 may be coplanar with each other.

The bit line BL may include a conductive layer 124 and a contact barrier layer 122. The contact barrier layer 122 may be disposed on the conductive layer 124. For example, the conductive layer 124 may include doped polysilicon, metal (e.g., Al, Cu, Ti, Ta, Ru, W, Mo, Pt, Ni, and/or Co), conductive metal nitride (e.g., TiN, TaN, WN, NON, TiAlN, TiSiN, TaSiN, and/or RuTiN), conductive metal silicide, and/or conductive metal oxide (e.g., PtO, RuO₂, IrO₂, SrRuO₃(SRO), (Ba, Sr)RuO₃ (BSRO), CoRuO₃ (CRO), and/or LaSrCoO (LSCO)), but aspects are not limited thereto.

For example, the contact barrier layer 122 may include tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbon nitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and/or a two-dimensional (2D) material.

In some embodiments, the contact barrier layer 122 and the conductive layer 124 may include a 2D (semiconductor) material. For example, the 2D material may include a 2D allotrope or a 2D compound, and may include graphene, carbon nanotubes, molybdenum disulfide (MoS₂), molybdenum diselenide (MoSe₂), tungsten diselenide (WSe₂), and/or tungsten disulfide (WS₂), but aspects are not limited thereto. That is, the 2D materials described above are merely a list of some examples, and the 2D materials that may be included in the semiconductor memory device of the present disclosure are not limited to the materials mentioned above.

The mold pattern 130 may be disposed on the upper surface of the bit line BL and the upper surface of the bit line insulating film 125. The mold pattern 130 may extend in the second direction D2. The mold patterns 130 may be aligned and spaced apart from each other in the first direction D1.

The mold pattern 130 may include an insulating material. For example, the mold pattern 130 may include silicon oxide, silicon nitride, silicon oxynitride, and/or a low-k insulating material.

A channel trench CH_T may be disposed on the upper surface of the bit line BL. A lower surface (e.g., bottom surface) of the channel trench CH_T may be defined as the upper surface of the bit line BL and the upper surface of the bit line insulating film 125. Both side surfaces (opposite side surfaces) of the channel trench CH_T may be defined by side surfaces of the mold pattern 130 facing each other (in the first direction D1 or in the second direction D2). The channel trench CH_T may extend in the second direction D2. The channel trenches CH T may be spaced apart from each other in the first direction D1 and/or the second direction D2.

The channel trench CH_T may expose (portions of) the upper surface of the bit line BL (and/or portions of the upper surface of the bit line insulating film 125).

The channel structure CH may be disposed on the upper surface of the bit line BL. The channel structure CH may be (electrically) connected to the bit line BL. The channel structures CH disposed on one bit line BL may be spaced apart from each other in the first direction D1.

The channel structure CH may be disposed in the channel trench CH T. The channel structure CH may be on (extend along) the side surface and the lower surface (e.g., bottom surface) of the channel trench CH_T. From a cross-sectional point of view, the channel structure CH may have an (approximately) “U” shape.

The channel structure CH may include a first vertical part CH_V1, a second vertical part CH_V2, and a horizontal part CH_H.

Each of the first vertical part CH_V1 and the second vertical part CH_V2 may be disposed on the side surface of the mold pattern 130. Each of the first vertical part CH_V1 and the second vertical part CH_V2 may extend in the third direction D3. In some embodiments, the third direction D3 may be perpendicular to the upper surface of the substrate 100. For example, the first vertical part CH_V1 may extend from one end of the horizontal part CH_H in the third direction D3, and the second vertical part CH_V2 may extend from the other end of the horizontal part CH_H in the third direction D3. The first vertical part CH_V1 and the second vertical part CH_V2 may be spaced apart from each other in the first direction D1.

The horizontal part CH_H may be disposed on (along) the upper surface of the bit line BL. The horizontal part CH_H may connect the first vertical part CH_V1 and the second vertical part CH_V2. In some embodiments, the horizontal part CH_H, the first vertical part CH_V1, and the second vertical part CH_V2 may be connected to each other to form a unitary structure. A unitary structure (e.g., the channel structure CH) herein may refer to a structure (e.g., a continuum) without a (visible) boundary between its sub-structures (e.g., the horizontal part CH_H, the first vertical part CH_V1, and the second vertical part CH_V2). However, aspects are not limited to the above. Unlike the illustration, for example, the horizontal part CH_H may be separated into two parts. For example, one separated part of the horizontal part CH_H may be connected to the first vertical part CH_V1, and the other separated part of the horizontal part CH_H may be connected to the second vertical part CH_V2. The gate separation structure 170 may be disposed between the separated horizontal parts CH_H.

The channel structure CH may include, for example, an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓN_{y}O, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O and/or InₓGa_{y}O, but aspects are not limited thereto. For example, the channel structure CH may include an indium gallium zinc oxide (IGZO). The channel structure CH may include a single layer or multiple layers of an oxide semiconductor (or oxide semiconductors). The channel structure CH may include an amorphous, crystalline, and/or polycrystalline oxide semiconductor.

In some embodiments, the channel structure CH may have a bandgap energy greater than that of silicon. For example, the channel structure CH may have a bandgap energy of (about) 1.5 eV to 5.6 eV. For example, the channel structure CH may have optimal channel performance when it has a bandgap energy of (about) 2.0 eV to 4.0 eV. For example, the channel structure CH may be polycrystalline or amorphous, but aspects are not limited thereto.

In some embodiments, the channel structure CH may include a 2D (semiconductor) material. For example, the 2D (semiconductor) material may include graphene, carbon nanotube, or a combination thereof.

In some embodiments, an upper surface of the mold pattern 130 and an upper surface of the channel structure CH may be disposed on the same plane each other. For example, the upper surface of the mold pattern 130 and the upper surface of the channel structure CH may be coplanar with each other. The upper surface of the channel structure CH may refer to any one of an upper surface of the first vertical part CH_V1 and an upper surface of the second vertical part CH_V2. In other words, a distance H1 from the upper surface of the bit line BL to the upper surface of the mold pattern 130 may be equal to a distance H2 from the upper surface of the bit line BL to the upper surface of the second vertical part CH_V2 (or to the upper surface of the first vertical part CH_V1). However, aspects are not limited to the above. For example, the upper surface of the channel structure CH may be disposed lower or higher than the upper surface of the mold pattern 130. The terms of relative vertical level, such as higher and lower, may be relative locations (e.g., distance) from a lower surface of the substrate 100 in the third direction D3. For example, a farther distance from the lower surface of the substrate 100 may be a higher vertical level. A closer distance from the lower surface of the substrate 100 may be a lower vertical level.

The word line WL may be disposed on the channel structure CH. The word line WL may intersect (e.g., overlap in the third direction D3) the bit line BL. The word line WL may extend in the second direction D2. The word line WL (a pair of adjacent word lines WL) may include a first word line WL1 and a second word line WL2.

Each of the first word line WL1 and the second word line WL2 may be disposed on the channel structure CH. Each of the first word line WL1 and the second word line WL2 may be disposed between the first vertical part CH_V1 and the second vertical part CH_V2 (in the first direction D1). The first word line WL1 may be disposed on one side of the horizontal part CH_H and the first vertical part CH_V1. The second word line WL2 may be disposed on one side of the horizontal part CH_H (e.g., on the opposite side of the horizontal part CH_H in the first direction D1 to the one side of the horizontal part CH_H on which the first word line WL1 is disposed) and the second vertical part CH_V2. The first word line WL1 and the second word line WL2 may be disposed to be spaced apart from each other in the first direction D1.

The width of the first word line WL1 may not be constant in the first direction D1. For example, a portion of the first word line WL1 disposed on the channel structure CH (e.g., a portion of the first word line WL1 overlapping with the channel structure CH in the first direction D1) may have a less width in the first direction D1 than a portion of the first word line WL1 not disposed on the channel structure CH (e.g., a portion of the first word line WL1 not overlapping with the channel structure CH in the first direction D1). That is, a portion of the first word line WL1 disposed between the channel structures CH (in the first direction D1) may have a less width in the first direction D1 than another portion of the first word line WL1 not disposed between the channel structures CH (in the first direction D1). The second word line WL2 may be configured with the same or similar width as the first word line WL1 in the first direction D1. For example, the first word line WL1 and the second word line WL2 may have a symmetrical shape to each other in the first direction D1.

For example, the word line WL may include doped polysilicon, metal (e.g., Al, Cu, Ti, Ta, Ru, W, Mo, Pt, Ni, and/or Co), conductive metal nitride (e.g., TiN, TaN, WN, NbN, TiAlN, TiSiN, TaSiN, and/or RuTiN), conductive metal silicide, and/or conductive metal oxide (e.g., PtO, RuO₂, IrO₂, SrRuO₃ (SRO), (Ba, Sr)RuO₃ (BSRO), CoRuO₃ (CRO), and/or LaSrCoO (LSCO)), but aspects are not limited thereto. The word line WL may include a single layer of each of the materials described above or multiple layers of the materials described above.

In some embodiments, the word line WL may include a 2D semiconductor material. For example, the 2D semiconductor material may include graphene, carbon nanotube, and/or a combination thereof.

In some embodiments, an upper surface of the first word line WL1 may be disposed lower than the upper surface of the first vertical part CH_V1. An upper surface of the second word line WL2 may be disposed lower than the upper surface of the second vertical part CH_V2. For example, a distance H3 from the upper surface of the bit line BL to the upper surface of the second word line WL2 (or the upper surface of the first word line WL1) may be less than the distance H2 from the upper surface of the bit line BL to the upper surface of the second vertical part CH_V2 (or the upper surface of the first vertical part CH_V1).

The gate insulating film 160 may be disposed between the word line WL and the channel structure CH. For example, the gate insulating film 160 may be disposed between the first word line WL1 and the first vertical part CH_V1 and between the second word line WL2 and the second vertical part CH_V2, respectively. In some embodiments, the gate insulating film 160 may be on the outer side surface and the lower surface of the first word line WL1 and the outer side surface and the lower surface of the second word line WL2. The gate insulating film 160 may be on (e.g., may be in contact with) the horizontal part CH_H. The gate insulating film 160 may extend parallel to the first word line WL1 and the second word line WL2 in the second direction D2. The first word line WL1 and the second word line WL2 may not be in contact with the channel structure CH due to the presence of the gate insulating film 160. For example, the word line WL (e.g., the first word line WL1 and the second word line WL2) may be spaced apart from the channel structured CH by the gate insulating film 160.

The gate insulating film 160 may include, for example, silicon oxide, silicon oxynitride, and/or a high-k material having a dielectric constant higher than that of the silicon oxide. The high-k material may include, for example, a metal oxide and/or a metal oxynitride. For example, the high-k material available as the gate insulating film 160 may include HfO₂, HfSiO, HfSiON, HfTaO, HfTiO, HfZrO, ZrO₂ and/or Al₂O₃, but aspects are not limited thereto.

The gate separation structure 170 may be disposed on the bit line BL and the bit line insulating film 125. The gate separation structure 170 may be disposed in the channel trench CH_T. The gate separation structure 170 may be disposed on the channel structure CH. In the semiconductor memory device according to some embodiments, the gate separation structure 170 may be in contact with the channel structure CH. The gate separation structure 170 may be on (e.g., may be in contact with) the horizontal part CH_H. The gate separation structure 170 may be spaced apart from the bit line BL (by the channel structure CH) in the third direction D3.

The gate separation structure 170 may be disposed between the first word line WL1 and the second word line WL2 to separate the first word line WL1 and the second word line WL2 in the first direction D1. The gate separation structure 170 may extend in the second direction D2 between the first word line WL1 and the second word line WL2.

The first word line WL1 may be disposed between the gate separation structure 170 and the first vertical part CH_V1 (in the first direction D1). The second word line WL2 may be disposed between the gate separation structure 170 and the second vertical part CH_V2 (in the first direction D1).

The gate separation structure 170 may include a horizontal part and a protrusion part. The horizontal part of the gate separation structure 170 may extend in the first direction D1. The protrusion part of the gate separation structure 170 may protrude from the horizontal part of the gate separation structure 170 toward the bit line BL in the third direction D3. The protrusion part of the gate separation structure 170 may be closer to the bit line BL than the horizontal part of the gate separation structure 170. The horizontal part of the gate separation structure 170 may be disposed on the upper surfaces of the first and second word lines WL1 and WL2. In some embodiments, the protrusion part of the gate separation structure 170 may be between the first and second word lines WL1 and WL2 in the first direction D1. For example, the horizontal part of the gate separation structure 170 may be on (e.g., may overlap in the third direction D3) the protrusion part of the gate separation structure 170 and the first and second word lines WL1 and WL2. For example, from a cross-sectional point of view, the gate separation structure 170 may have a (approximately) “T” shape.

The gate separation structure 170 may include the gate separation liner film 172, the gate separation filling film 174, and the gate separation capping film 176. In some embodiments, the protrusion part of the gate separation structure 170 may include the gate separation filling film 174, and the horizontal part of the gate separation structure 170 may include the gate separation capping film 176. The gate separation liner film 172 may extend along the upper surface and inner side surface of the first word line WL1 and the upper surface and inner side surface of the second word line WL2. For example, the gate separation liner film 172 may be on the lower surface and the side surfaces of the gate separation filling film 174 and the lower surface and the side surfaces of the gate separation capping film 176. The gate separation liner film 172 may extend along the horizontal part CH_H of the channel structure CH. The gate separation liner film 172 may be on (e.g., may be in contact with) the horizontal part CH_H. The gate separation liner film 172 may extend along the gate insulating film 160 that protrudes further (farther from the substrate 100 in the third direction D3) than the upper surface of the first word line WL1 and the upper surface of the second word line WL2. Unlike the illustration, the gate separation liner film 172 may not extend along the gate insulating film 160 that protrudes further (farther from the substrate 100 in the third direction D3) than the upper surface of the first word line WL1 and the upper surface of the second word line WL2.

The gate separation filling film 174 may be disposed on the gate separation liner film 172. The gate separation capping film 176 may be disposed on the gate separation filling film 174. In some embodiments, the gate separation liner film 172 on lower surfaces and side surfaces of the gate separation capping film 176 and on a lower surface and side surfaces of the gate separation filling film 174. The gate separation liner film 172 may be on an upper surface and the inner side surface of the word line WL. For example, from a cross-sectional view point, the first word line WL1 and the second word line WL2 may be surrounded by the gate separation liner film 172 and the gate insulating film 160. Each of the gate separation liner film 172, the gate separation filling film 174, and the gate separation capping film 176 may include (e.g., may be formed of) an insulating material. Unlike the illustration, the gate separation structure 170 may be a single layer. For example, the gate separation liner film 172, the gate separation filling film 174, and the gate separation capping film 176 may form a unitary structure (the gate separation structure 170). The horizontal part of the gate separation structure 170 and the protrusion part of the gate separation structure 170 may form a unitary structure.

In some embodiments, an upper surface of the gate separation structure 170 may be disposed on the same plane the upper surface of the mold pattern 130. The upper surface of the gate separation structure 170 may be coplanar with the upper surface of the mold pattern 130. For example, a distance from the upper surface of the bit line BL to the upper surface of the gate separation structure 170 may be equal to the distance from the upper surface of the bit line BL to the upper surface of the mold pattern 130. However, aspects are not limited to the above.

A contact trench 140_T may be disposed on the channel structure CH and the gate separation structure 170. The contact trench 140_T may be on the gate insulating film 160 and the mold pattern 130. The contact trench 140_T may be disposed in the interlayer insulating film 190 (on the channel structure CH, the gate insulating film 160, the gate separation structure 170, and/or the mold pattern 130). A side surface of the contact trench 140_T may be defined as the interlayer insulating film 190. A lower surface of the contact trench 140_T may expose a portion of the channel structure CH, the gate insulating film 160, and the gate separation structure 170. For example, the lower surface of the contact trench 140_T may expose the upper surface of the first vertical part CH_V1 and the upper surface of the second vertical part CH_V2. In some embodiments, the lower surface of the contact trench 140_T may expose a portion of the mold pattern 130.

The pad contact layer 140 may be disposed in the contact trench 140_T. The pad contact layer 140 may be disposed on the side surface and the lower surface of the contact trench 140_T. The pad contact layer 140 may include a bottom part 140_BP and a sidewall 140_SW. The bottom part 140_BP of the pad contact layer 140 may be disposed on the lower surface of the contact trench 140_T. For example, the bottom part 140_BP may be on the upper surfaces of the channel structure CH (e.g., the upper surface of the first vertical part CH_V1 and the upper surface of the second vertical part CH_V2), the upper surface of the gate insulating film 160, the upper surface of the gate separation structure 170, and/or the upper surface of the mold pattern 130. The sidewall 140_SW of the pad contact layer 140 may be disposed on the side surface of the contact trench 140_T. For example, the sidewall 140_SW may be on the interlayer insulating film 190.

In some embodiments, the pad contact layer 140 may be conformally disposed. For example, the thickness of the sidewall 140_SW of the pad contact layer 140 in the first direction D1 and the thickness of the bottom part 140_BP of the pad contact layer 140 in the third direction D3 may be equal to each other. In some embodiments, the sidewall 140_SW and the bottom part 140_BP may form a unitary structure. For example, in a cross-sectional view, the pad contact layer 140 may have an (approximately) “U” shape. However, aspects are not limited to the above.

The landing pad 180 may be disposed on the pad contact layer 140. The landing pad 180 may be in contact with the pad contact layer 140. The pad contact layer 140 (e.g., the bottom part 140_BP) may be between the landing pad 180 and the channel structure CH (e.g., the first vertical part CH_V1 and/or the second vertical part CH_V2) in the third direction D3. The landing pad 180 may be electrically connected to the channel structure CH through the pad contact layer 140.

When viewed in a plan view, the landing pad 180 may have various shapes such as a circle, an ellipse, a rectangle, a square, a rhombus, a hexagon, etc. When viewed in a plan view, the landing pad 180 may be arranged in various forms such as a matrix form, a zigzag form, a honeycomb form, etc. along the first and second directions D1 and D2. The upper surface of the landing pad 180 may be on the same plane the upper surface of the interlayer insulating film 190, but aspects are not limited thereto. The upper surface of the landing pad 180 and the upper surface of the interlayer insulating film 190 may be coplanar with each other.

The sidewall 140_SW of the pad contact layer 140 may be disposed between the landing pad 180 and the interlayer insulating film 190 (in the first direction D1). The sidewall 140_SW of the pad contact layer 140 may overlap the interlayer insulating film 190 in the first direction D1. In some embodiments, the sidewall 140_SW of the pad contact layer 140 may surround at least a portion of a side surface 180_SS of the landing pad 180. For example, as illustrated in FIG. 3, the sidewall 140_SW of the pad contact layer 140 may completely surround the side surface 180_SS of the landing pad 180. As another example, as illustrated in FIG. 8, the sidewall 140_SW of the pad contact layer 140 may surround a portion of the side surface 180 SS of the landing pad 180. Unlike the illustration in FIG. 3, a portion of the side surface 180_SS of the landing pad 180 may be in contact with the interlayer insulating film 190.

The bottom part 140_BP of the pad contact layer 140 may be disposed on a lower surface 180_BS of the landing pad 180. The bottom part 140_BP of the pad contact layer 140 may be disposed along the lower surface 180_BS of the landing pad 180. The bottom part 140_BP of the pad contact layer 140 may cover (or overlap in the third direction D3 with) the lower surface 180_BS of the landing pad 180. The length of the bottom part 140_BP of the pad contact layer 140 in the first direction D1 may be greater than the length of the landing pad 180 in the first direction D1. The length of the bottom part 140_BP of the pad contact layer 140 in the first direction D1 may be greater than the width of (each of) the first and second vertical parts CH_V1 and CH_V2 in the first direction D1.

A portion of the bottom part 140_BP of the pad contact layer 140 may be disposed between the landing pad 180 and the channel structure CH (in the third direction D3). The bottom part 140_BP of the pad contact layer 140 may be in contact with the channel structure CH. For example, the bottom part 140_BP of the pad contact layer 140 may be in contact with the upper surface of the first vertical part CH_V1 and the upper surface of the second vertical part CH_V2, respectively.

A portion of the bottom part 140_BP of the pad contact layer 140 may be disposed between the landing pad 180 and the gate insulating film 160 (in the third direction D3) and between the landing pad 180 and the gate separation structure 170 (in the third direction D3), respectively. In some embodiments, the bottom part 140_BP of the pad contact layer 140 may be in contact with the upper surface of the gate insulating film 160 and the upper surface of the mold pattern 130, respectively.

The bottom part 140_BP of the pad contact layer 140 may overlap the word lines WL1 and WL2 in the third direction D3. In other words, at least a portion of the bottom part 140_BP of the pad contact layer 140 may be disposed between the landing pad 180 and the word lines WL1 and WL2 (in the third direction D3).

The interlayer insulating film 190 may be disposed on the mold pattern 130 and the gate separation structure 170. The interlayer insulating film 190 may fill a space between adjacent pad contact layers 140 of a plurality of pad contact layers 140. The interlayer insulating film 190 may include an insulating material.

The pad contact layer 140 may include an oxide semiconductor. For example, the pad contact layer 140 may include indium oxide (InO). In some embodiments, an interface between the pad contact layer 140 and the channel structure CH may not be visible.

If the landing pad 180 and the channel structure CH directly is in direct contact each other, contact resistance between the landing pad 180 and the channel structure CH may increase. However, in the semiconductor memory device according to some embodiments of the present disclosure, the pad contact layer 140 may be disposed between the channel structure CH and the landing pad 180. Because the pad contact layer 140 contacts each of the channel structure CH and the landing pad 180, the contact resistance between the pad contact layer 140 and the channel structure CH and between the pad contact layer 140 and the landing pad 180 may decrease. Accordingly, electrical characteristics and reliability of the semiconductor memory device can be improved.

The landing pad 180 may include (e.g., may be formed of) a doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, and/or a combination thereof, but aspects are not limited thereto.

Referring to FIG. 4, the concentrations of a first element A1 and a second element A2 included in the landing pad 180, the pad contact layer 140, and the channel structure CH will be described below. The first element A1 and the second element A2 may be any one of materials other than oxygen.

The pad contact layer 140 and the channel structure CH may include the first element A1. The landing pad 180 may include no amount of or a small (non-significant) amount of the first element A1. Although it is illustrated that the first element A1 is included in the landing pad 180 adjacent to the boundary between the landing pad 180 and the pad contact layer 140, it should be understood that a small (non-significant) amount of the first element A1 is diffused from the pad contact layer 140 to the landing pad 180. The concentration of the first element A1 of the pad contact layer 140 may be greater than that of the first element A1 of the channel structure CH. For example, the first element A1 may be indium (In). The term, concentration, herein, may refer to mass concentration, molar concentration, number concentration, volume concentration, atomic concentration, etc.

The channel structure CH may include the second element A2. The pad contact layer 140 (and the landing pad 180) may include no amount of or a small (non-significant) amount of the second element A2. Although it is illustrated that the second element A2 is included in the pad contact layer 140 adjacent to the boundary between the pad contact layer 140 and the channel structure CH, it should be understood that a small (non-significant) amount of second element A2 is diffused from the channel structure CH to the pad contact layer 140. For example, the second element A2 may include gallium (Ga), zinc (Zn), etc. However, aspects are not limited to the above. For example, the second element A2 may include a material other than indium (In) of the composition materials of the channel structure CH described above.

In FIG. 4, it is illustrated that the concentration of the second element A2 included in the channel structure CH is greater than that of the first element A1, but this should be understood as an example. The concentration of the first element A1 and the concentration of the second element A2 of the channel structure CH may change according to the composition ratio of the material included in the channel structure CH. For example, the concentration of the first element A1 of the channel structure CH may be equal to or less than the concentration of the second element A2.

Referring back to FIGS. 1 to 8, an etching stop film 210 may be disposed on the landing pad 180 and the interlayer insulating film 190. In some embodiments, the etching stop film 210 may be on the pad contact layer 140. The etching stop film 210 may expose (at least a portion of) the landing pad 180.

The capacitor structure CAP may be disposed on the landing pad 180 and the interlayer insulating film 190. In some embodiments, the capacitor structure CAP may be on the pad contact layer 140. The capacitor structure CAP may store a signal received from a transistor in a peripheral circuit structure (e.g., row and column decoders, sense amplifier, etc.) of the semiconductor memory device. The capacitor structure CAP may be used as a data storage element electrically connected to the transistor. For example, the capacitor structure CAP may store electric charges under the control of the transistor.

The capacitor structure CAP may include a lower electrode 222, the dielectric film 224, and the upper electrode 226.

The lower electrode 222 may be disposed on the landing pad 180. The lower electrode 222 may be electrically connected to the landing pad 180. A portion of the lower electrode 222 may be disposed in the etching stop film 210. For example, the lower electrode 222 may extend through the etching stop film 210 and connected to the landing pad 180.

For example, the lower electrode 222 may include a conductive metal material (e.g., cobalt (Co), titanium (Ti), nickel (Ni), tungsten (W), molybdenum (Mo), etc.), a metal nitride (e.g., titanium nitride (TiN), titanium silicon nitride (TiSiN), titanium aluminum nitride (TiAlN), tantalum aluminum nitride (TaAlN), tungsten nitride (WN), etc.), a noble metal material (e.g., platinum (Pt), ruthenium (Ru), iridium (Ir), etc.), a conductive oxide film (e.g., PtO, RuO₂, IrO₂, SrRuO₃ (SRO), (Ba, Sr)RuO₃ (BSRO), CoRuO₃ (CRO), LaSrCoO (LSCO), etc.), and/or a metal silicide film. However, aspects are not limited to the above.

Although not illustrated, in some embodiments, at least one supporter may be disposed between the lower electrodes 222. The supporter may support the lower electrode 222.

The dielectric film 224 may be disposed on the lower electrode 222. The dielectric film 224 may extend along the profile of the lower electrode 222. For example, the dielectric film 224 may include a high dielectric constant material including a silicon oxide, a silicon nitride, a silicon oxynitride, and/or a metal. Although it is illustrated that the dielectric film 224 is a single film, it is only for convenience of description, and aspects are not limited thereto. Unlike the illustration, the dielectric film 224 may include a plurality of films.

The upper electrode 226 may be disposed on the dielectric film 224. The upper electrode 226 may fill an empty space between the lower electrodes 222. For example, the upper electrode 226 may include an element semiconductor material film and/or a compound semiconductor material film. The upper electrode 226 may include, for example, a doped n-type or p-type impurity.

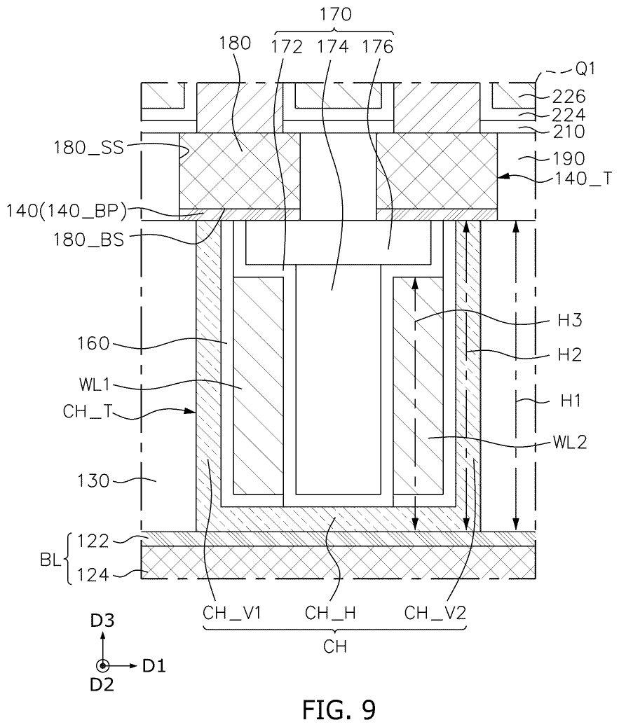

FIG. 9 is a diagram provided to explain a semiconductor memory device according to some embodiments of the present disclosure. For reference, FIG. 9 may correspond to an enlarged view of the region Q1 of FIG. 2. For convenience of description, different configurations from those described above with reference to FIGS. 1 to 8 will be mainly described.

Referring to FIG. 9, in the semiconductor memory device according to some embodiments, the pad contact layer 140 may include the bottom part 140_BP, but may not include the sidewall 140_SW of FIG. 3.

The pad contact layer 140 may be disposed in the contact trench 140_T. The pad contact layer 140 may be disposed on the lower surface of the contact trench 140_T. The bottom part 140_BP of the pad contact layer 140 may be disposed along the lower surface of the contact trench 140 T. The description of the bottom part 140_BP of the pad contact layer 140 may be the same as that described above with reference to FIGS. 1 to 8.

The landing pad 180 may be disposed on the pad contact layer 140. The lower surface 180_BS of the landing pad 180 may be in contact with the bottom part 140_BP of the pad contact layer 140. The length of the landing pad 180 in the first direction D1 may be the same (equal) as the length of the pad contact layer 140 in the first direction D1. The side surface 180_SS of the landing pad 180 may be in contact with the interlayer insulating film 190.

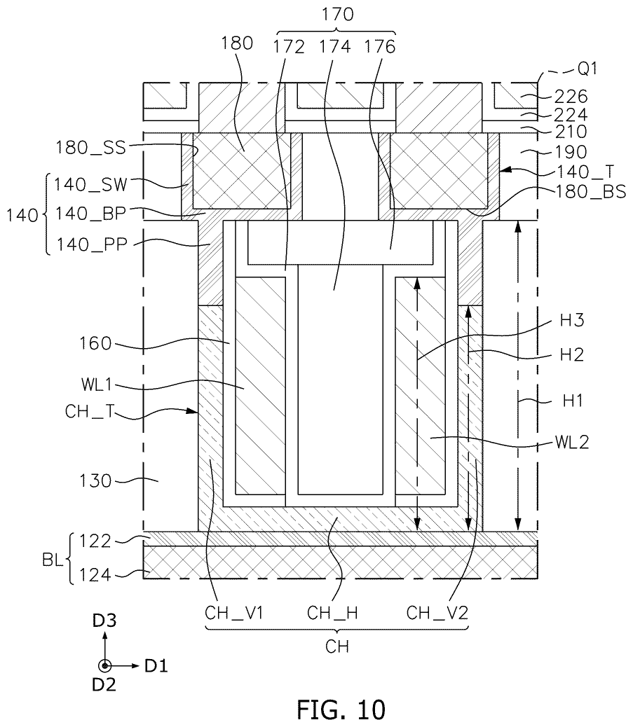

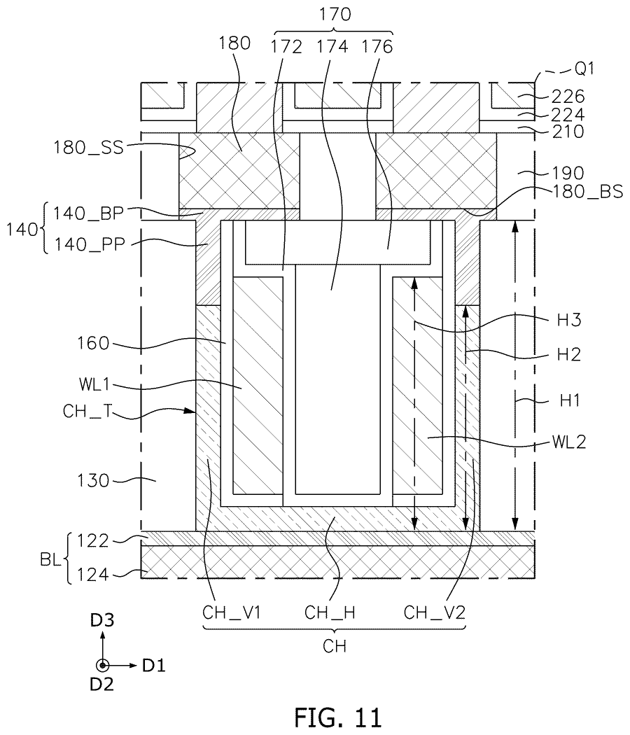

FIG. 10 is a diagram provided to explain a semiconductor memory device according to some embodiments of the present disclosure. FIG. 11 is a diagram provided to explain a semiconductor memory device according to some embodiments of the present disclosure. For reference, each of FIGS. 10 and 11 may correspond to an enlarged view of the region Q1 of FIG. 2. For convenience of description, different configurations from those described in FIGS. 1 to 8 will be mainly described.

Referring to FIGS. 10 and 11, in the semiconductor memory device according to some embodiments, the pad contact layer 140 may further include a protrusion part 140_PP. For example, as illustrated in FIG. 10, the pad contact layer 140 may include the sidewall 140_SW, the bottom part 140_BP, and the protrusion part 140_PP. As another example, as illustrated in FIG. 11, the pad contact layer 140 may include the bottom part 140_BP and the protrusion part 140_PP, but may not include the sidewall 140 SW.

The protrusion part 140_PP of the pad contact layer 140 may protrude from the bottom part 140_BP of the pad contact layer 140 toward the channel structure CH in the third direction D3. The protrusion part 140_PP may be disposed between the mold pattern 130 and the gate insulating film 160 (in the first direction D1). For example, the protrusion part 140_PP may be disposed between the mold pattern 130 and the gate insulating film 160 which are disposed in an upper portion of the channel structure CH.

The protrusion part 140_PP may be in contact with the channel structure CH. For example, the protrusion part 140_PP may be in contact with each of (the upper surface of) the first vertical part CH_V1 and (the upper surface of) the second vertical part CH_V2. A portion of the protrusion part 140_PP may overlap each of the first word line WL1 and the second word line WL2 in the first direction D1.

The uppermost portion of the channel structure CH may be disposed lower than the upper surface of the mold pattern 130. For example, the distance H2 from the upper surface of the bit line BL to the upper surface of the second vertical part CH_V2 (or the upper surface of the first vertical part CH_V1) may be less than the distance H1 from the upper surface of the bit line BL to the upper surface of the mold pattern 130.

The upper surface of the first word line WL1 may be disposed higher than the upper surface of the first vertical part CH_V1. The upper surface of the second word line WL2 may be disposed higher than the upper surface of the second vertical part CH_V2. For example, the distance H3 from the upper surface of the bit line BL to the upper surface of the second word line WL2 (or the upper surface of the first word line W1) may be greater than the distance H2 from the upper surface of the bit line BL to the upper surface of the second vertical part CH_V2 (or the upper surface of the first vertical part CH_V1).

A portion of the gate insulating film 160 may protrude in the third direction D3 further (farther from the upper surface of the bit line BL in the third direction D3) than the upper surface of the first word line WL1 and the upper surface of the second word line WL2. For example, the uppermost portion of the gate insulating film 160 may be disposed higher than the upper surface of the first word line WL1 and the upper surface of the second word line WL2.

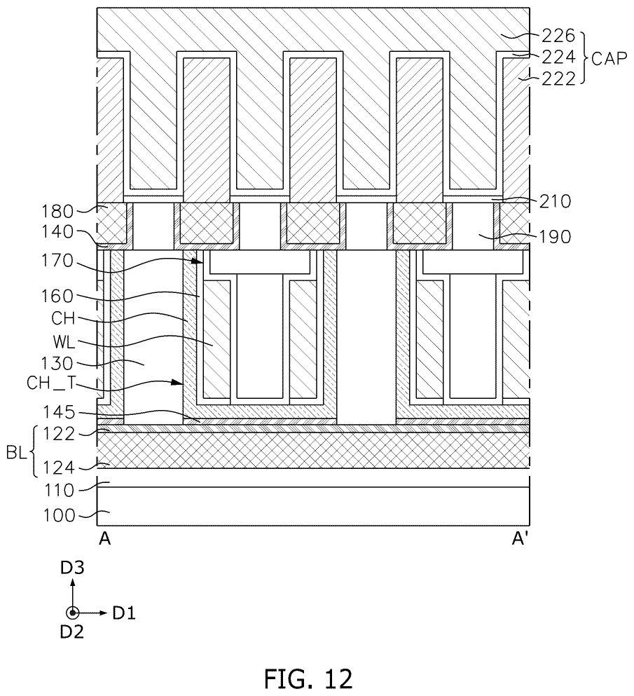

FIG. 12 is a diagram provided to explain a semiconductor memory device according to some embodiments of the present disclosure. For reference, FIG. 12 may correspond to a cross-sectional view taken along line A-A′ of FIG. 1. For convenience of description, different configurations from those described in FIGS. 1 to 8 will be mainly described.

Referring to FIG. 12, the semiconductor memory device according to some embodiments may further include a bit line contact layer 145.

The bit line contact layer 145 may be disposed on the upper surface of the bit line BL. The bit line contact layer 145 may be disposed between the channel structure CH and the bit line BL. For example, the bit line contact layer 145 may be disposed between the horizontal part CH H of the channel structure CH and the contact barrier layer 122 of the bit line BL.

In some embodiments, the bit line contact layer 145 may include the same material as the pad contact layer 140. For example, the bit line contact layer 145 may include indium oxide (InO).

The bit line contact layer 145 may be in contact with the channel structure CH to lower the contact resistance between the bit line BL and the channel structure CH. Accordingly, electrical characteristics of the semiconductor memory device can be improved.

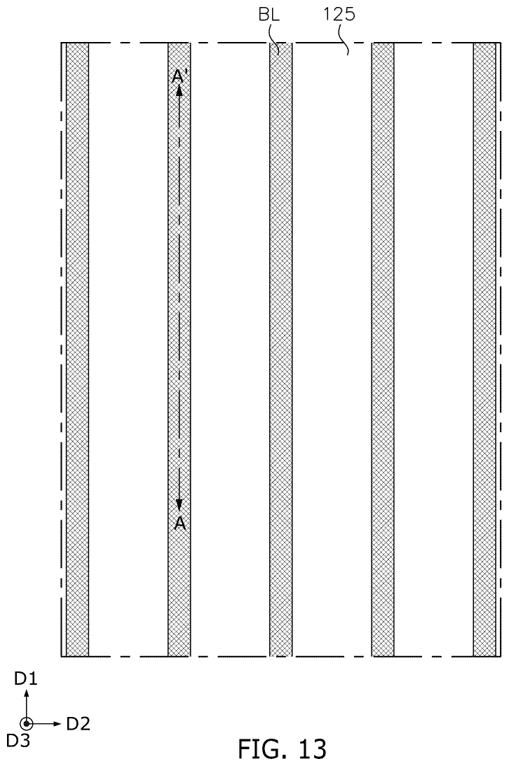

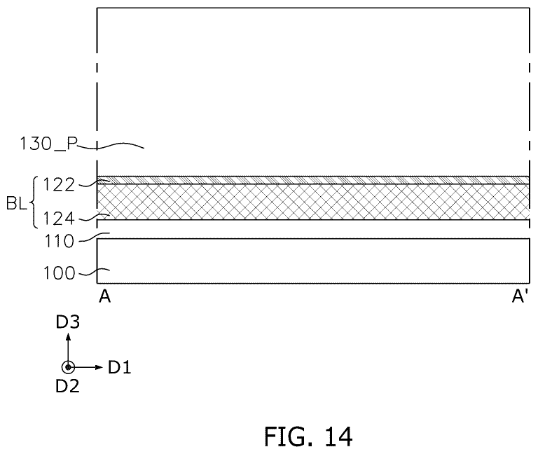

FIGS. 13 to 19 are diagrams showing intermediate stages, provided to explain a method for manufacturing a semiconductor memory device according to some embodiments of the present disclosure. For reference, FIG. 13 is a plan view provided to explain a method for manufacturing a semiconductor memory device. FIGS. 14 to 19 may correspond to a cross-sectional view taken along line A-A′ of FIG. 13.

Referring to FIGS. 13 and 14, the wiring insulating film 110, the bit line BL, and the bit line insulating film 125 may be formed on the substrate 100.

The substrate 100 may be a semiconductor substrate. For example, the substrate 100 may include silicon (Si), silicon germanium (SiGe), indium antimonide (InSb), lead telluride (PbTe), indium arsenide (InAs), indium phosphide (InP), gallium arsenide (GaAs), gallium antimonide (GaSb), etc. However, aspects are not limited to the above.

In some embodiments, a plurality of transistors (electrically) connected to the bit line BL may be disposed in the substrate 100. For example, a sensing transistor, a transmission transistor, a driving transistor, etc. may be disposed in the substrate 100. The type of the transistors may vary depending on the layout design of the semiconductor memory device. A region in the substrate 100 where the plurality of transistors are disposed may be referred to as a peripheral circuit area.

The wiring insulating film 110 may be formed on the substrate 100. The bit line BL and the bit line insulating film 125 may be formed on the wiring insulating film 110. The bit line BL may extend in the first direction D1 on the wiring insulating film 110. Adjacent bit lines BL may be disposed to be spaced apart from each other in the second direction D2. The bit line insulating film 125 may be disposed between adjacent bit lines BL.

A pre-mold insulating film 130_P may be formed on the upper surface of the bit line BL and the upper surface of the bit line insulating film 125. The pre-mold insulating film 130_P may cover (or overlap in the third direction D3) the bit line BL and the bit line insulating film 125.

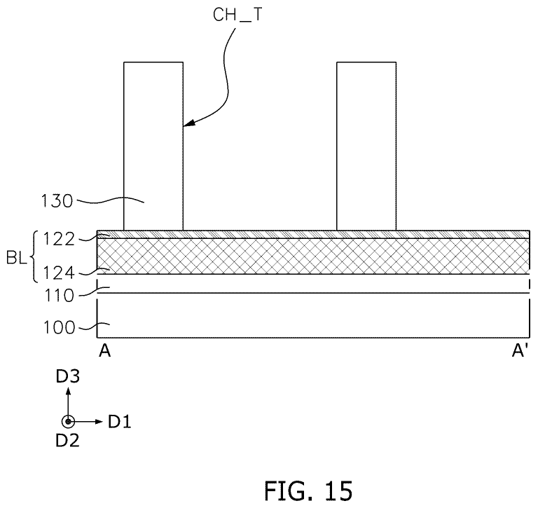

Referring to FIGS. 14 and 15, the pre-mold insulating film 130_P may be etched to form the mold pattern 130.

Specifically, a hard mask pattern may be formed on the pre-mold insulating film 130_P. The hard mask pattern may expose a portion of the pre-mold insulating film 130_P. The pre-mold insulating film 130_P exposed from the hard mask pattern may be etched to form the mold pattern 130. The mold pattern 130 may extend in the second direction D2. The mold patterns 130 may be disposed to be spaced apart from each other in the first direction D1.

The channel trench CH_T may be formed on the bit line BL. The lower surface of the channel trench CH_T may be defined as (a portion of) the upper surface of the bit line BL and (a portion of) the upper surface of the bit line insulating film 125. Both side surfaces (e.g., opposite side surfaces in the first direction D1) of the channel trench CH_T may be defined by side surfaces of the mold pattern 130 facing each other in the first direction D1. The channel trenches CH_T may be spaced apart from each other in the first direction D1 and the second direction D2.

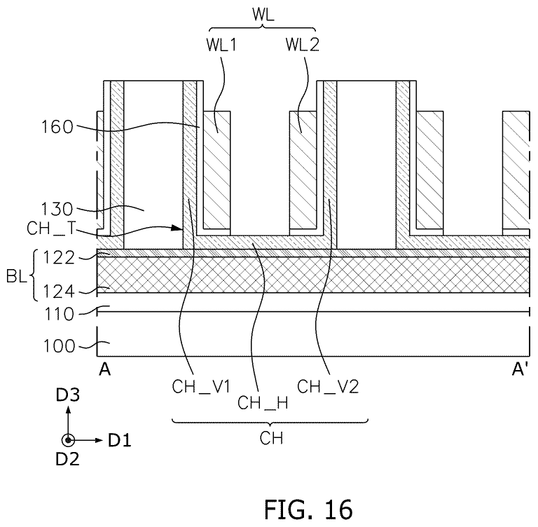

Referring to FIG. 16, the channel structure CH may be formed in the channel trench CH_T, and the gate insulating film 160 and the word line WL may be formed on the channel structure CH.

Specifically, the channel structure CH may be formed along both side surfaces (e.g., opposite side surfaces in the first direction D1) and the lower surface of the channel trench CH_T. The channel structure CH may include a first vertical part CH_V1, a second vertical part CH_V2, and a horizontal part CH_H. The first vertical part CH_V1 and the second vertical part CH_V2 may be formed on the side surface of the mold pattern 130. The horizontal part CH_H may be formed on the upper surface of the bit line BL.

The gate insulating film 160 and the word line WL may be formed on the channel structure CH.

The word line WL may extend in the second direction D2. The word line WL may include a first word line WL1 and a second word line WL2. The first word line WL1 may be disposed on one side surface (inner side surface) of the first vertical part CH_V1. The second word line WL2 may be disposed on one side surface (inner side surface) of the second vertical part CH_V2. The first word line WL1 and the second word line WL2 may be disposed to be spaced apart from each other in the first direction D1. For example, the inner side surface of the first vertical part CH_V1 and the inner side surface of the second vertical part CH_V2 may face to each other in the first direction D1.

The gate insulating film 160 may be disposed between the first word line WL1 and the first vertical part CH_V1 and between the second word line WL2 and the second vertical part CH_V2. The gate insulating film 160 may extend along the inner side surface of the first vertical part CH_V1, the inner side surface of the second vertical part CH_V2, and a portion of the upper surface of the horizontal part CH_H.

Unlike the illustration, in some embodiments, the gate insulating film 160 may extend along the upper surface of the horizontal part CH_H. The gate insulating film 160 disposed between the first word line WL1 and the first vertical part CH_V1, and the gate insulating film 160 disposed between the second word line WL2 and the second vertical part CH_V2 may be connected to each other.

Unlike the illustration, in some embodiments, the channel structure CH may be separated into two parts. For example, the horizontal part CH_H may be separated into two parts. One separated part of the horizontal part CH_H may be connected to the first vertical part CH_V1, and the other separated part of the separated horizontal part CH_H may be connected to the second vertical part CH_V2. The upper surface of the bit line BL may be exposed between the separated horizontal parts CH_H.

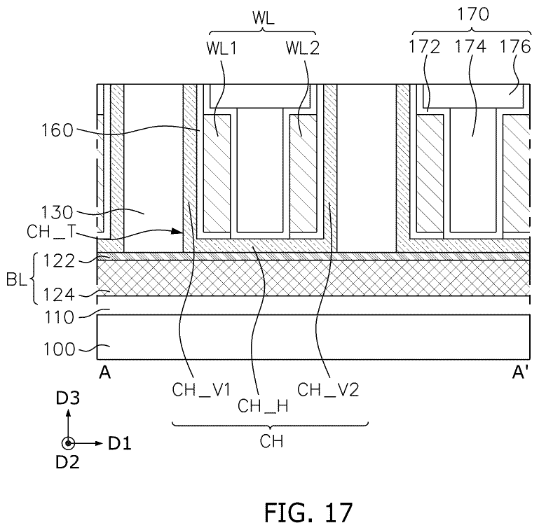

Referring to FIG. 17, the gate separation structure 170 may be formed on the channel structure CH.

Specifically, the gate separation structure 170 may be formed on the channel structure CH and the word lines WL1 and WL2. The gate separation structure 170 may be disposed between the first word line WL1 and the second word line WL2 to separate the first word line WL1 and the second word line WL2 in the first direction D1. The gate separation structure 170 may include the gate separation liner film 172, the gate separation filling film 174, and the gate separation capping film 176.

The upper surface of the gate separation structure 170 and the upper surface of the channel structure CH may be disposed on the same plane each other. The upper surface of the gate separation structure 170 and the upper surface of the channel structure CH may be coplanar with each other. The upper surface of the channel structure CH may include the upper surface of the first vertical part CH_V1 and the upper surface of the second vertical part CH_V2.

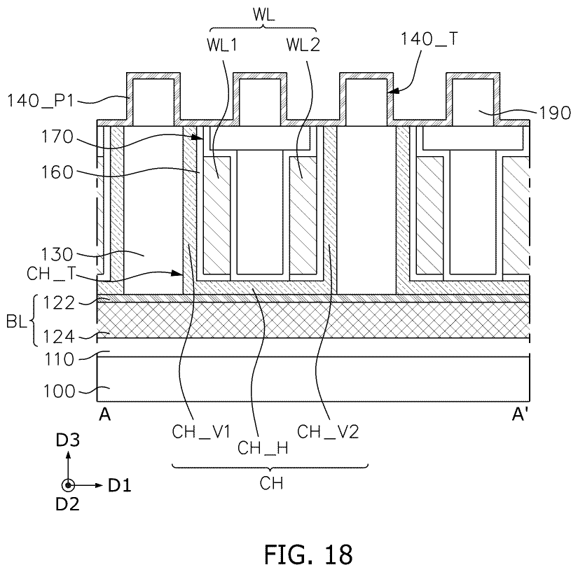

Referring to FIG. 18, the interlayer insulating film 190 may be formed on the mold pattern 130 and the gate separation structure 170, and a first pre-contact layer 140_P1 may be formed (on the interlayer insulating film 190, the gate separation structure 170, the channel structure CH, the mold pattern 130, and/or the gate insulating film 160).

Specifically, an insulating layer may be formed on the mold pattern 130 and the gate separation structure 170. The insulating layer may cover (or overlap in the third direction D3) the mold pattern 130 and the gate separation structure 170. A mask pattern may be formed on the insulating layer. The mask pattern may expose a portion of the insulating layer. The insulating layer may be patterned using a mask pattern as a mask, and the interlayer insulating film 190 may be formed.

The contact trench 140_T may be formed in the interlayer insulating film 190. The contact trench 140_T may be a portion of the insulating layer removed by patterning. A side surface of the contact trench 140_T may be defined as the interlayer insulating film 190. The lower surface of the contact trench 140_T may expose a portion of the channel structure CH, the gate insulating film 160, and the gate separation structure 170. In some embodiments, the lower surface of the contact trench 140_T may expose a portion of the mold pattern 130.

The first pre-contact layer 140_P1 may be formed on the interlayer insulating film 190 and the contact trench 140_T. The first pre-contact layer 140_P1 may be formed along the upper surface of the interlayer insulating film 190 and the side surface and the lower surface of the contact trench 140_T. In some embodiments, the first pre-contact layer 140_P1 may be conformally formed.

For example, the first pre-contact layer 140_P1 may be formed by any one of physical vapor deposition (PVD), chemical vapor deposition (CVD), and atomic layer deposition (ALD). However, aspects are not limited to the above.

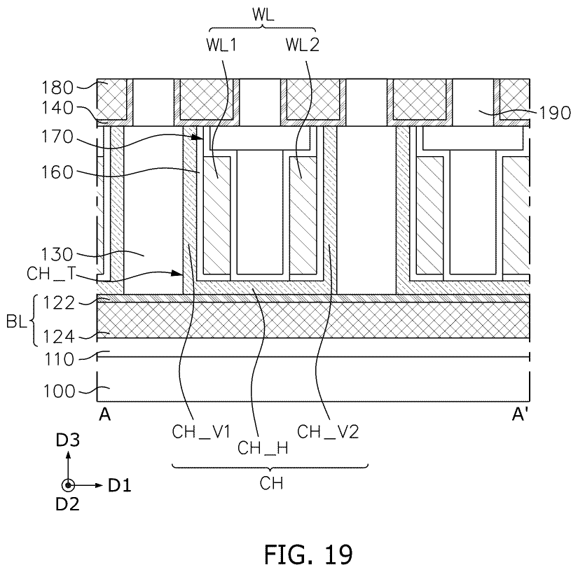

Referring to FIGS. 18 and 19, the pad contact layer 140 and the landing pad 180 may be formed in the contact trench 140_T.

Specifically, the landing pad 180 may be formed on the first pre-contact layer 140_P1. The upper surface of the landing pad 180 and a portion of the first pre-contact layer 140_P1 may be removed. For example, a portion of the first pre-contact layer 140_P1 may be removed by the chemical mechanical polishing (CMP) process. However, aspects are not limited to the above. In some embodiments, the upper surface of the landing pad 180 and the upper surface of the interlayer insulating film 190 may be disposed on the same plane each other. For example, the upper surface of the landing pad 180 and the upper surface of the interlayer insulating film 190 may be coplanar with each other.

The pad contact layer 140 may include a sidewall and a bottom part. The description of the pad contact layer 140 may be the same as that described above with reference to FIGS. 1 to 8.

Referring to FIG. 2, the etching stop film 210 and the capacitor structure CAP may be formed.

The etching stop film 210 may be disposed on the landing pad 180 and the interlayer insulating film 190. The etching stop film 210 may expose (a portion of) the landing pad 180. In some embodiments, the etching stop film 210 may be on the pad contact layer 140.

The capacitor structure CAP may be formed on the landing pad 180 and the interlayer insulating film 190. In some embodiments, the capacitor structure CAP may be on the pad contact layer 140. The capacitor structure CAP may include the lower electrode 222, the dielectric film 224, and the upper electrode 226. The description of the capacitor structure CAP may be the same as that described above with reference to FIGS. 1 to 8.

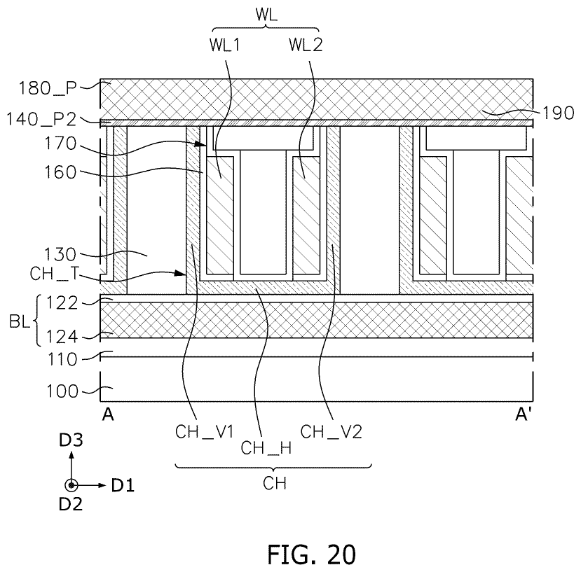

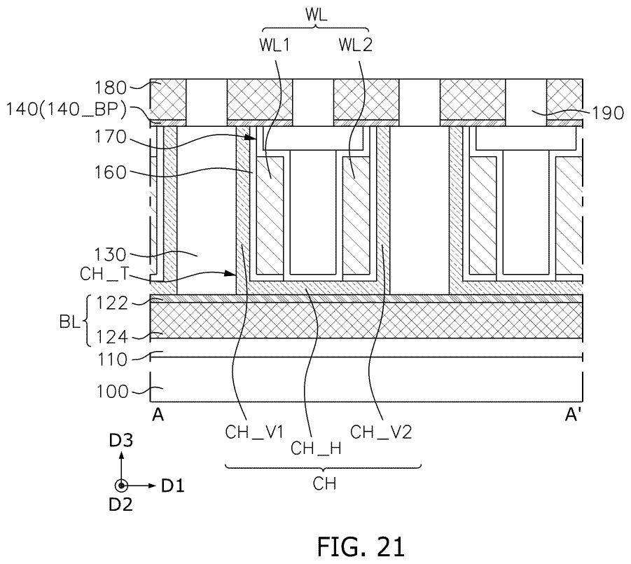

FIGS. 20 and 21 are diagrams showing intermediate stages, provided to explain a method for manufacturing a semiconductor memory device according to some embodiments of the present disclosure. For reference, the method illustrated in FIG. 20 may be a manufacturing method performed after the manufacturing method described above with reference to FIGS. 13 to 17.

Referring to FIGS. 17 and 20, a second pre-contact layer 140_P2 and a pre-landing pad 180_P may be formed in order on the mold pattern 130, the channel structure CH, and the gate separation structure 170. In some embodiments, the second pre-contact layer 140_P2 and the pre-landing pad 180_P may be formed on the gate insulating film 160.

The second pre-contact layer 140_P2 may cover (or overlap in the third direction D3) the upper surface of the mold pattern 130, the upper surface of the channel structure CH, and the upper surface of the gate separation structure 170. The pre-landing pad 180_P may cover (or overlap in the third direction D3) an upper surface of the second pre-contact layer 140_P2.

Referring to FIGS. 20 and 21, the second pre-contact layer 140_P2 and the pre-landing pad 180_P may be patterned, and the interlayer insulating film 190 may be formed.

Specifically, a hard mask pattern may be formed on the free landing pad 180_P. The hard mask pattern may expose a portion of the free landing pad 180_P. The pre-landing pad 180_P and the second pre-contact layer 140_P2 may be patterned using the hard mask pattern as a mask. The patterned pre-landing pad 180_P and the second pre-contact layer 140_P2 may expose (a portion of) the mold pattern 130 and (a portion of) the gate separation structure 170.

The interlayer insulating film 190 may be formed on (exposed) the mold pattern 130 and the gate separation structure 170. The description of the landing pad 180 and the pad contact layer 140 may be the same as that described above with reference to FIG. 9.

Referring to FIG. 2, the etching stop film 210 and the capacitor structure CAP may be formed.

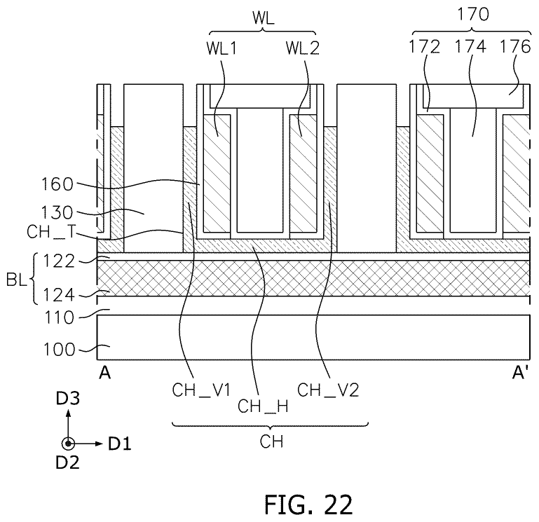

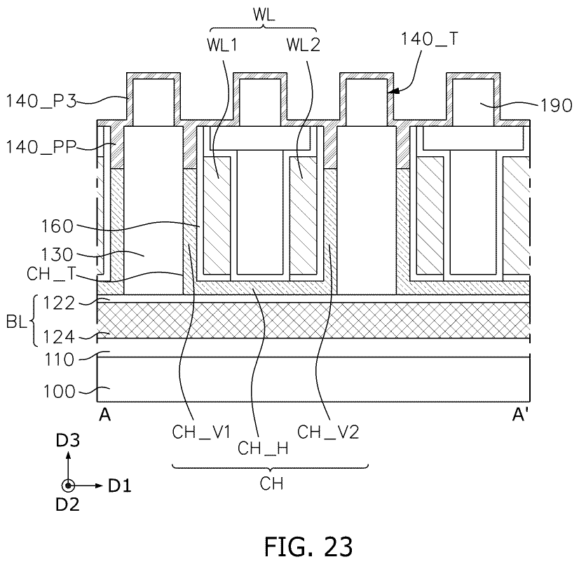

FIGS. 22 and 23 are diagrams showing intermediate stages, provided to explain a method for manufacturing a semiconductor memory device according to some embodiments of the present disclosure. For reference, the method illustrated in FIG. 22 may be a manufacturing method performed after the manufacturing method described above with reference to FIGS. 13 to 17.

Referring to FIGS. 17 and 22, a portion of the channel structure CH may be removed.

Specifically, a portion of the first and second vertical parts CH_V1 and CH_V2 disposed between the mold pattern 130 and the gate insulating film 160 may be removed. Accordingly, the height of the first vertical part CH_V1 and the second vertical part CH_V2 may be reduced. The height of an element may refer to a length of the element in the third direction D3. The (reduced) height of the first vertical part CH_V1 may be equal to the (reduced) height of the second vertical part CH_V2. The height of the first vertical part CH_V1 (and the height of the second vertical part CH_V2) may be less than the height of the mold pattern 130.

In some embodiments, the uppermost portion of the first vertical part CH_V1 (or the second vertical part CH_V2) may be disposed lower than the uppermost portion of the first word line WL1 (or the uppermost portion of the second word line WL2). In other words, the distance from the upper surface of the bit line BL to the upper surface of the first vertical part CH_V1 (or the second vertical part CH_V2) may be less than the distance from the upper surface of the bit line BL to the upper surface of the first word line WL1 (or the upper surface of the second word line WL2). However, aspects are not limited to the above.

Referring to FIGS. 22 and 23, the interlayer insulating film 190 may be formed on the mold pattern 130 and the gate separation structure 170, and a third pre-contact layer 140_P3 may be formed (thereon).

Specifically, an insulating layer may be formed on the mold pattern 130 and the gate separation structure 170. The insulating layer may cover (or overlap in the third direction D3) the mold pattern 130 and the gate separation structure 170. A mask pattern may be formed on the insulating layer. The mask pattern may expose a portion of the insulating layer. The insulating layer may be patterned using a mask pattern as a mask, and the interlayer insulating film 190 may be formed.

The third pre-contact layer 140_P3 may be formed on the upper surface of the interlayer insulating film 190 and a portion exposed between the interlayer insulating films 190. The third pre-contact layer 140_P3 may include the protrusion part 140_PP. The protrusion part 140_PP may be disposed between the mold pattern 130 and the gate insulating film 160 which are disposed in the upper portion of the channel structure CH.

The landing pad 180 may be formed on the third pre-contact layer 140_P3, and a portion of the third pre-contact layer 140_P3 may be removed to form the pad contact layer 140.

Referring to FIGS. 2 and 10, the etching stop film 210 and the capacitor structure CAP may be formed.

Although certain aspects of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

1. A semiconductor memory device, comprising:
a substrate;
a bit line on the substrate, wherein the bit line extends in a first direction that is parallel with an upper surface of the substrate;
a channel structure on the bit line, wherein the channel structure extends in a second direction that is parallel with the upper surface of the substrate and perpendicular to the first direction, and wherein the channel structure includes a vertical part extending in a third direction that is perpendicular to the upper surface of the substrate;
a word line on the channel structure;
a pad contact layer on the vertical part of the channel structure;
a landing pad on the pad contact layer; and
a capacitor structure electrically connected to the landing pad,
wherein the pad contact layer includes a bottom part on a lower surface of the landing pad.

2. The semiconductor memory device according to claim 1, wherein a length of the bottom part in the first direction is equal to or greater than a length of the landing pad in the first direction.

3. The semiconductor memory device according to claim 1, wherein the pad contact layer further includes a sidewall connected to the bottom part, and
wherein the sidewall of the pad contact layer is on a side surface of the landing pad.

4. The semiconductor memory device according to claim 1, wherein at least a portion of the bottom part of the pad contact layer is between the landing pad and the word line in the third direction.

5. The semiconductor memory device according to claim 1, wherein at least a portion of the pad contact layer overlaps the landing pad in the first direction.

6. The semiconductor memory device according to claim 1, wherein the pad contact layer further includes a protrusion part that protrudes from the bottom part toward the channel structure.

7. The semiconductor memory device according to claim 6, wherein the protrusion part of the pad contact layer overlaps the word line in the first direction.

8. The semiconductor memory device according to claim 1, wherein the vertical part of the channel structure includes a first vertical part and a second vertical part that is spaced apart from the first vertical part in the first direction,
wherein the word line includes a first word line on a side surface of the first vertical part and a second word line on a side surface of the second vertical part, and
wherein the semiconductor memory device further includes a gate separation structure between the first word line and the second word line in the first direction.

9. The semiconductor memory device according to claim 8, wherein at least a portion of the bottom part of the pad contact layer is between the landing pad and the gate separation structure in the third direction.

10. The semiconductor memory device according to claim 1, wherein the landing pad includes a first element at a first concentration, the pad contact layer includes the first element at a second concentration, and the channel structure includes the first element at a third concentration, and
wherein the third concentration is greater than the first concentration and is less than the second concentration.

11. A semiconductor memory device, comprising:
a substrate;
a bit line on the substrate, wherein the bit line extends in a first direction that is parallel with an upper surface of the substrate;
a channel structure on the bit line, wherein the channel structure extends in a second direction that is parallel with the upper surface of the substrate and perpendicular to the first direction, wherein the channel structure includes a first vertical part extending in a third direction that is perpendicular to the upper surface of the substrate, and wherein the channel structure further includes a second vertical part that is spaced apart from the first vertical part in the first direction;
a first word line on a side surface of the first vertical part and extending in the second direction;
a second word line on a side surface of the second vertical part and extending in the second direction;
a gate separation structure between the first word line and the second word line in the first direction;
an interlayer insulating film on the gate separation structure;
a contact trench in the interlayer insulating film, wherein the contact trench overlaps a portion of the channel structure and a portion of the gate separation structure in the third direction;
a pad contact layer in the contact trench, wherein the pad contact layer is in contact with the channel structure;
a landing pad on the pad contact layer; and
a capacitor structure electrically connected to the landing pad.

12. The semiconductor memory device according to claim 11, wherein a length of the pad contact layer in the first direction is greater than a length of the first vertical part of the channel structure in the first direction.

13. The semiconductor memory device according to claim 11, wherein the pad contact layer surrounds at least a portion of a side surface of the landing pad.

14. The semiconductor memory device according to claim 11, wherein a bottom part of the pad contact layer overlaps a lower surface of the landing pad in the third direction.

15. The semiconductor memory device according to claim 11, wherein the landing pad is spaced apart from the gate separation structure in the third direction.

16. The semiconductor memory device according to claim 11, wherein an uppermost portion of the pad contact layer is farther than an uppermost portion of the gate separation structure from an upper surface of the bit line in the third direction.

17. The semiconductor memory device according to claim 11, wherein an upper surface of the pad contact layer and an upper surface of the landing pad are coplanar with each other.

18. The semiconductor memory device according to claim 11, further comprising:
a gate insulating film between the first vertical part of the channel structure and the first word line in the first direction, wherein the pad contact layer is on an upper surface of the gate insulating film.

19. The semiconductor memory device according to claim 11, wherein the channel structure further includes a horizontal part that connects the first vertical part and the second vertical part, and
wherein the horizontal part extends along an upper surface of the bit line.

20. A semiconductor memory device, comprising:
a substrate;
a bit line on the substrate, wherein the bit line extends in a first direction that is parallel with an upper surface of the substrate;
a channel structure on the bit line, wherein the channel structure extends in a second direction that is parallel with the upper surface of the substrate and perpendicular to the first direction, and wherein the channel structure includes a first vertical part extending in a third direction that is perpendicular to the upper surface of the substrate, and wherein the channel structure further includes a second vertical part that is spaced apart from the first vertical part in the first direction;
a first word line on a side surface of the first vertical part and extending in the second direction;
a second word line on a side surface of the second vertical part and extending in the second direction;
a gate separation structure between the first word line and the second word line in the first direction;
a pad contact layer on an upper surface of the first vertical part;
a landing pad on the pad contact layer; and
a capacitor structure electrically connected to the landing pad,
wherein the pad contact layer is between the landing pad and the first vertical part and between the landing pad and the gate separation structure,
wherein the landing pad includes a first element at a first concentration,
wherein the pad contact layer includes the first element at a second concentration, and
wherein the second concentration is greater than the first concentration.
